(19) United States
(12) Patent Application Publication
(10) Pub. No.: US 2006/0102855 A1
(43) Pub. Date: May 18, 2006

(54) Contaminant removal device and method

(76) Inventor: John Baker, Manchester (GB)

Correspondence Address: WELSH & FLAXMAN LLC, 2000 DUKE STREET, SUITE 100, ALEXANDRIA, VA, 22314, US

(21) Appl. No.: 10/541,926

(22) PCT Filed: Jan. 9, 2004
(86) PCT No.: PCT/GB04/00083

§ 371 Date: Jan. 9, 2006

(30) Foreign Application Priority Data
Jan. 13, 2003 (GB) 0300688.9

(51) Int. Cl. H01J 37/08

(52) U.S. Cl. 250/492.21

(57) ABSTRACT

A device for removing non-conducting contaminants from an organic material, the devise comprises an ion beam generator for generating, in use, an ion beam a conductive surface is moveable, in use, with respect to the ion beam. A detector generates an output based upon detected characteristics of the ion beam and the deflector separates the detected non-conducting contaminants from the organic material based on the output of the detection system.

This invention relates to a device for removing contaminants from a flow of material. In particular, it relates to a device which detects and removes non-conducting contaminants from an organic material such as tobacco stem.

The presence of contaminants in organic materials such as food and tobacco is an unwanted and potentially dangerous problem, and the quality and safety of the organic material, and therefore the end product, can be reduced by such contaminants being present.

Traditional methods of removing contaminants manually, for example by passing the organic material along a conveyor belt and removing contaminants by hand, are time-consuming and can be affected by human error. Similarly, any kind of sieving process is unreliable, as no contaminant which is larger than or equal to the pieces of organic material in size can be filtered. A thorough sieving process may also be extremely time-consuming and difficult to maintain. Processes currently in use are therefore unreliable, and there is a need in industry for a quick and reliable method for removing contaminants from organic materials.

The present invention seeks to overcome the aforementioned problems, and to provide an efficient method of detecting and removing contaminant from organic material, thereby improving the quality of the final product to be manufactured.

According to the present invention there is provided a device for removing non-conducting contaminants from an organic material, the device comprising:

an ion beam generator for generating, in use, an ion beam;

a conductive surface, separated from the ion beam; and

a contaminant detection system and a deflector wherein;

the detection system generates an output based upon detected characteristics of the ion beam, and

the deflector separates the detected non-conducting contaminants from the organic material based on the output of the detection system.

According to the present invention there is also provided a method for removing non-conducting contaminants from an organic material, the method comprising the steps of:

generating an ion beam;

directing said ion beam towards a conductive surface;

detecting changes in the ion beam to detect the non-conducting contaminants; and

controlling a deflector via the detector output to

separate the non-conductive contaminants from the organic material.

The continuous ion beam may be generated by applying a current to a plurality of conductive points.

The charged non-conducting contaminants may be electrostatically attracted towards the conductive surface, which may be grounded or oppositely charged to the ion beam in use.

The detection system may also contain an electronic sensor.

The present invention introduces an improved method for the detection and removal of non-conducting contaminants from organic material. The use of electrostatics allows a faster and more thorough method of detection and removal than methods currently implemented in industry as it does not rely on manual operation, and human error can therefore be eliminated. The flow of organic material does not rest in any part of the device, making the device itself easier to clean and maintain, and the contaminants are detected without contact. The present invention leads to improved reliability in the processing of materials such as tobacco stem, and an improved quality in the end products.

Examples of the present invention will now be described with reference to the accompanying drawings, in which:

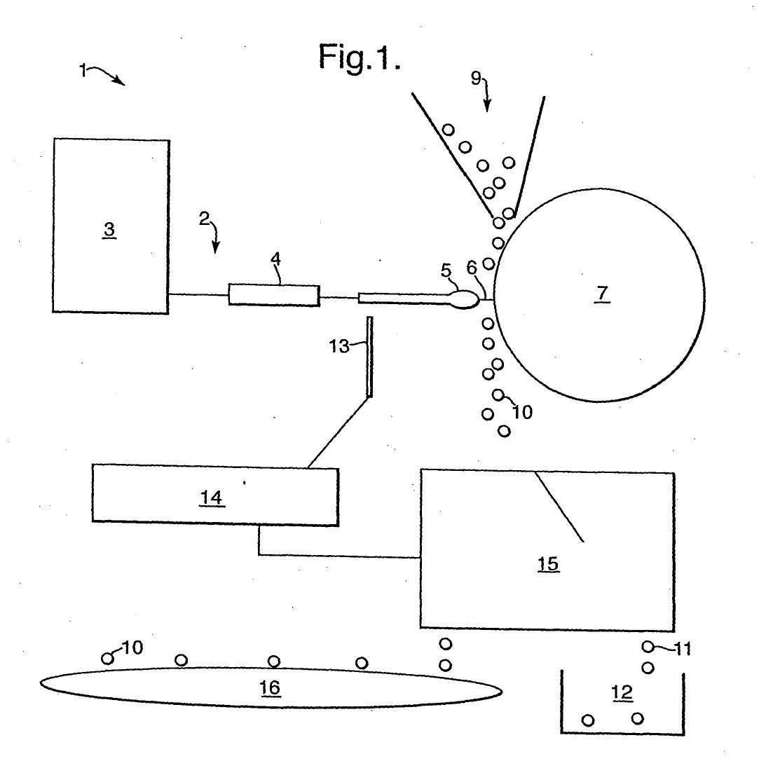

FIG. 1 is a side view of a device according to the invention.

Referring to FIG. 1, a device 1 according to the invention has an ion beam generator 2, a conductive, rotatable drum 7, a scraper 8 and a reject bin 12. The ion beam generator 2 typically comprises a plurality of high voltage generators 3, a resistor 4 of around 100 MΩ and a plurality of conductive needle points 5 which are placed at intervals along the width of the device. When the device is switched on, the high voltage generators 3 apply a current to each of the plurality of needle points 5 via the 100 MΩ resistor 4. The high voltage is typically 30 000V positive. The conductive, rotatable drum is connected to electrical ground or is oppositely charged to the ion beam. A continuous positive ion discharge in the form of a plurality of beams 6 occurs between the plurality of needle points 5 and the drum 7. In some cases the needle point 5 may be hollow to allow a gas under pressure to be ejected therefrom to improve ion transport, cooling and focussing.

When the device 1 is in use, tobacco stem 10 is introduced into a chute 9 by a pneumatic conveyor (not shown), and falls into the device. The tobacco stem 10 is spread across the width of the device and falls through the gap between the plurality of needle points 5 and the drum 7, which rotates at the same rate as the flow of tobacco stem 10 when the device is in use. The tobacco stem 10 therefore flows through the ion beams 6. Because tobacco stem, like all organic material, contains moisture and impurities, it is conductive. At a high voltage such as 30 000V and at a regulated current the beams 6 pass through the tobacco stem 10 without interruption.

If, however, any type of non-conducting contaminant 11, such as plastic material, is positioned in the beams 6, the contaminant 11 is given a positive charge and is attracted to the conductive, rotatable drum 7. If the contaminants 11 are light in weight they stick to the drum 7 and are carried to a scraper (not shown). The scraper then deposits the contaminants in a reject bin 12.

If, however, the contaminants 11 are heavier, other detection and removal means are required. Accordingly, the device 1 also comprises means for detecting and removing heavier contaminants. When in use, the device operates as follows. The non-conducting contaminants 11 will interrupt some of the ion beams 6 and will also reflect some of the ions as they pass through the gap between the plurality of needles 5 and the drum 7. This interruption can be measured in order to detect the presence of the contaminants and remove them from the flow of organic material.

Firstly, the interruption will cause the current of the ion beam 6 to change, and this can be measured using opto-couplers and amplifiers (not shown).

Secondly, a sensor 13 can be placed below the ion beam generator 2. If the sensor 13 is positioned at a slightly greater distance from the plurality of needle points 5 than the drum 7 (shown in dotted lines), an easier route to ground will be presented for an ion beam that has been interrupted. The ion beam 6 will completely transfer to the sensor (electrode?) 13 and can be easily and safely measured by a simple electronic comparator 14.

As shown in FIG. 1, the sensor 13 can also be positioned so that the gap between the sensor 13 and the plurality of needle points 5 is much greater than the gap between the plurality of needle points 5 and the drum 7. In this case, the system acts in an analogue mode whereby the number of reflected ions is determined by the average diameter of the contaminant 11. This method of detection is capable, after amplification, of producing even greater sensitivity for the detection of small contaminants at high speed.

After the contaminants have been detected, they must be removed reliably from the flow of organic material. The output of the opto-couplers (not shown) or comparator 14 can be connected to a pneumatic deflector 15, and drives the deflector 15. The deflector then moves according to the output so as to place detected contaminants 11 in a reject bin 12, or to allow tobacco stem 10 that is uncontaminated to continue uninterrupted onto a conveyor belt 16.

The present invention therefore provides a fast, robust and reliable method of finding contaminants, such as plastic material, in organic materials, such as tobacco stem.

The above example shows a device which is operated in air, but it would also be possible for a device to operate in a air/gas or gas only environment to improve the quality and control of the ion beam. Furthermore, whilst in the above example the electrical potential is such that the ion beam generator is at a positive potential with respect to the surface of the drum, this is not an essential requirement. In certain circumstances it would be beneficial to have the generator at a negative potential to improve the detection characteristics. Furthermore, by providing an alternating potential, possibly alternating between positive and negative values, detection can be further improved and can allow better penetration of the organic material from which the contaminant needs to be separated.

1. A device for removing non-conducting contaminants from an organic material, the device compromising:
an ion beam generator for generating, in use, an ion beam
a conductive surface, spread apart from the ion beam; and
a contaminant detection system and deflector wherein;
the detection system generates an output based upon detected characteristics of the ion beam
the deflector separates the detected non-conducting contaminants from the organic material based on the output of the detection system.

2. A device according to claim 1, wherein the ion beam generator comprises:
a plurality of conductive points;
a generator, which, in use, generates and applies a current to the plurality of conductive points in order to generate a continuous ion discharge form the plurality of conductive points.

3. A device according to claim 1, wherein the conductive points are provided by hollow needles.

4. A device according to claim 1, wherein the conductive surface moves with respect to the ion beam generator.

5. A device according to claim 4, wherein the conductive surface is a rotatable conductive drum.

6. A device according to claim 1, arranged such that in use, the ion beam is directed towards the surface and the contaminant-containing organic material flows through the beam, so that non-conducting contaminants therein become electrostatically charges and are deflected from the direction of flow and removed from the organic material.

7. A device according to claim 6, arranged such that, in use, the non-conducting contaminants are electrostatically attracted towards the conductive surface.

8. A device according to claim 7, further compromising a scraper for removing the non-conducting contaminants attracted to the conductive surface.

9. A device according to claim 1 wherein the conductive surface is connected to the ground.

10. A device according to claim 1 wherein, in use, the conductive surface is oppositely charged to the ion beam.

11. A device according to claim 1, wherein the organic material is tobacco stem.

12. A device according to claim 1, wherein the non-conducting contaminants are plastics material.

13. A device according to claim 1, wherein the detection system compromises means for monitoring the current of the ion beam once it has been reflected from the conductive surface and detects the contaminants on the basis of the monitored current.

14. A device according to claim 13, wherein the detection system compromises:
an electronic sensor, which provides a preferred route to ground for an ion beam interrupted by a contaminant; and
means for monitoring the intensity of said interrupted ion beam to detect contaminants.

15. A device according to claim 14, further compromising means for monitoring the number of reflected ions in the interrupted ion beam, in order to detect the size of the contaminants.

16. A method for removing non-conducting contaminants from an organic material, the method compromising the steps of:
generating an ion beam;
directing said ion beam towards the conductive surface;
detecting changes in the ion beam to detect the non-conducting contaminants; and
controlling a deflector via the detector output to separate the non-conductive contaminants from the organic material.

17. A method according to claim 16, wherein a continuous ion discharge is generated from a plurality of conductive points by applying a current to the plurality of conductive points.

18. A method according to claim 16, wherein said conductive surface rotates.

19. A method according to claim 16, further compromising the steps of electrostatically charging non-conducting contaminants in the flow of organic material by passing said organic material through the ion beam; and deflecting the non-conducting contaminants from the direction of flow and thereby removing them from the organic material.

20. A method according to claim 19, wherein the non-conducting contaminants are electrostatically attracted towards the conductive surface.

21. A method according to claim 20, wherein the non-conducting contaminants are scraped from the conductive surface.

22. A method according to claim 16, further compromising the steps of:
monitoring the current of an ion beam reflected from the conductive surface; and
detecting the contaminants on the basis of the monitored current.

23. A method according to claim 16, wherein the sensor is positioned so as to monitor the intensity of an ion beam interrupted by a contaminant.

24. A method according to claim 23, wherein the sensor is positioned so as to monitor the number of reflected ions in the interrupted ion beam, in order to detect the size of the contaminant.
